(19) United States
(12) Patent Application Publication
(10) Pub. No.: US 2014/0072829 A1
(43) Pub. Date: Mar. 13, 2014

(54) THIN FILM STRUCTURE INCLUDING ORDERED ALLOY AND METHOD FOR MANUFACTURING THE THIN FILM STRUCTURE

(71) Applicants: TOHOKU UNIVERSITY, Sendai-shi (JP); FUJI ELECTRIC CO., LTD., Kawasaki-shi (JP)

(72) Inventors: Yuki INABA, Matsumoto-shi (JP); Takehito SHIMATSU, Sendai-shi (JP)

(21) Appl. No.: 13/936,863

(22) Filed: Jul. 8, 2013

(30) Foreign Application Priority Data
Sep. 11, 2012 (JP) 2012-199609

(51) Int. Cl. G11B 5/62; B81B 3/00; C23C 28/02; H01L 43/10

(52) U.S. Cl. CPC G11B 5/62; H01L 43/10; B81B 3/0091; C23C 28/021
USPC 428/831.1; 428/457; 428/141; 428/650; 427/250

(57) ABSTRACT

The present invention provides: a thin film structure including an ordered alloy in which atoms are orderly arranged using an inexpensive substrate; and a method for manufacturing the thin film structure. Specifically, the thin film structure includes a substrate, a plating layer formed on the substrate and made of one selected from the group consisting of NiPMo and NiPW, and an ordered alloy disposed on the plating layer. The method for manufacturing the thin film structure includes the steps of: forming a plating layer on a substrate, the plating layer being made of one selected from the group consisting of NiPMo and NiPW; and forming an ordered alloy on the plating layer. The vacuum degree immediately before the ordered alloy is formed is 7.0×10⁻⁷ Pa or less. In the step of forming the ordered alloy, a process gas has an impurity concentration of 5 ppb or lower.

### CROSS-REFERENCES TO RELATED APPLICATIONS

This application claims the benefit of Japanese Patent Application No. 2012-199609, filed Sep. 11, 2012, which is hereby incorporated by reference herein in its entirety.

### BACKGROUND OF THE INVENTION

1. Field of the Invention

The present invention relates to a thin film structure including an ordered alloy (alloy having an ordered structure in which atoms are orderly arranged) and a method for manufacturing the same. Further, the present invention relates to various application devices including such a thin film structure. Particularly, when the alloy in the ordered structure is a magnetic material, the thin film structure of the present invention can be preferably used as a magnetic thin film structure, which demonstrates excellent magnetic properties attributable to the structure, and used in various application devices using the magnetic thin film structure.

2. Description of the Related Art

Ordered alloys in which atoms are orderly arranged have drawn attention due to excellent properties attributable to structures thereof. Preferable examples of applying such ordered alloys include various devices manufactured by using a magnetic thin film having a thickness in the order of nm and including at least one ferromagnetic element such as iron, cobalt, or nickel in an ordered alloy. Recently, for example, a magnetic recording medium, a tunnel magneto-resistance (MR) element, a magnetoresistive random access memory (MRAM), and a micro-electromechanical system (MEMS) device, and the like have been attracted attention and actively studied.

First of all, a magnetic recording medium will be described as an example of the various devices using a magnetic thin film. A magnetic recording medium is used in a magnetic recording device, such as a hard disk, a magneto optical drive (MO) disk, or a magnetic tape. The magnetic recording method includes longitudinal magnetic recording and perpendicular magnetic recording.

Heretofore, the longitudinal magnetic recording has been employed, in which magnetic patterns horizontal to the surface of a hard disk, for example, are recorded. However, recently, the perpendicular magnetic recording enabling higher recording density has been mainly employed, in which magnetic patterns perpendicular to the disk surface are recorded.

Various studies have been conducted on media for which this perpendicular magnetic recording is used (perpendicular magnetic recording medium). For example, the following techniques are disclosed.

Patent Literature 1 discloses a perpendicular magnetic recording medium including at least an underlayer, a magnetic layer, and a protective layer sequentially formed on a substrate. The magnetic layer has a granular structure which includes: ferromagnetic crystal grains essentially composed of a Co—Pt alloy; and nonmagnetic grain boundaries essentially composed of oxide and surrounding the crystal grains. The underlayer is an element of any of Cu, Pd, and Au, or an alloy made of any two or more elements of Cu, Pd, Pt, Ir, and Au. The perpendicular magnetic recording medium has low noise characteristics, excellent thermal stability, writing characteristics, and capability of high-density recording, and can be manufactured at low cost.

At present, a crystalline film of a Co—Pt-based alloy is mainly used as a magnetic layer of a perpendicular magnetic recording medium. The crystalline film of the Co—Pt-based alloy has a crystal orientation controlled in such a manner that a c axis of the Co—Pt-based alloy having a hexagonal close-packed structure (hcp) is perpendicular to a film surface (i.e., the c plane is parallel to the film surface). This enables perpendicular magnetic recording.

As one method for controlling magnetic properties of a magnetic layer, there is known a method for forming a granular magnetic layer having a structure in which a nonmagnetic non-metallic substance such as oxide or nitride surrounds the peripheries of ferromagnetic crystal grains.

In the granular magnetic layer, the grain boundary phase of the nonmagnetic non-metallic substance physically separates the ferromagnetic grains from one another. This narrows the transition regions of recording bits and restricts the fluctuation without excessively increasing the magnetic interaction among the ferromagnetic grains. Thus, low noise characteristics are produced.

In recent years, discrete track media (DIM) having grooves formed between tracks are actively developed to reduce mutual magnetic influences of tracks adjacent to each other for the purpose of raising a recording density of a perpendicular magnetic recording medium. Moreover, bit patterned media (BPM) having artificially orderly arranged magnetic dots (or magnetic grains) are also actively developed in order to achieve 1-bit recording per magnetic dot (or magnetic grain).

Furthermore, also proposed are heat- or thermal-assisted magnetic recording (HAMR or TAMR), energy-assisted recording with microwave (MAMR), and so forth, in order to obtain a perpendicular magnetic recording medium, which allows recording on a magnetic film having a high coercivity. Studies are also actively made on magnetic recording media to which these recording methods are applied.

Next, description will be given of a tunnel magneto-resistance element (TMR) as another example of the various devices using a magnetic thin film and a magnetoresistive random access memory (MRAM) using TMR. Conventional memories such as a flash memory and a dynamic random-access memory (DRAM) use electrons in a memory cell to record information. In contrast, MRAM is a memory, which uses as a recording medium a magnetic material, as similar to a hard disk and the like.

MRAM has address access time of approximately 10 ns and cycle time of approximately 20 ns. Hence, MRAM is readable and writable approximately 5 times faster than DRAM, that is, as fast as a static random-access memory (SRAM). Moreover, MRAM has an advantage of achieving high integration and low power consumption of approximately 1/10 of that of a flash memory.

Here, TMR used in MRAM can be constructed, for example, in the form of a laminate, in which a ferromagnetic thin film is formed on an anti-ferromagnetic thin film. Various techniques therefor are disclosed.

Patent Literature 2 discloses an exchange coupled element in which an anti-ferromagnetic layer and a ferromagnetic layer are sequentially stacked on a substrate, the ferromagnetic layer thus being exchange-coupled to the anti-ferromagnetic layer. The anti-ferromagnetic layer has an ordered phase of a Mn—Ir alloy (Mn₃Ir). Patent Literature 2 discloses a schematic sectional view of TMR, and a spin-valve type magneto-resistance element including the exchange coupled element. This element is also a laminate, in which a ferromagnetic thin film is formed on an anti-ferromagnetic thin film, as similar to the above TMR.

In addition, description will be given of a micro-electromechanical system (MEMS) device as another example of various devices using a magnetic thin film. The MEMS device is a generic term for devices in which a mechanical component, a sensor, an actuator, and/or an electronic circuit are integrated on one silicon substrate, glass substrate, organic material, or the like.

Application examples of the MEMS device include a digital micromirror device (DMD) which is one of optical elements in a projector, a micro nozzle used in a head portion of an inkjet printer, various sensors such as a pressure sensor, an acceleration sensor, and a flow sensor, and the like. The application of these devices is expected nowadays not only in the manufacturing industries but also in the medical field and so forth.

There is a demand for any of the above various devices (magnetic recording medium, TMR, MRAM, and HEMS device) using a magnetic thin film for improving magnetic properties of the magnetic thin film, specifically improving a uniaxial magnetic anisotropy (Kᵤ). The development of such a magnetic thin film exhibiting an excellent Kᵤ value is believed to greatly contribute to increases in capacity and/or recording density of recording media and memories in the future.

For example, for a magnetic recording layer of a perpendicular magnetic recording medium, the following recording layer is proposed for achieving high recording density. Specifically, the recording layer includes grains or dots each having a structure in which a hard layer and a soft layer are stacked, such as those of an ECC (exchange coupled composite), a hard/soft stack, an exchange spring, and the like.

However, in order for these magnetic recording media to sufficiently demonstrate the properties and achieve high thermal stability, excellent saturation recording characteristics, and so forth, the hard layer needs to be formed of a perpendicular magnetization film exhibiting a Kᵤ value of approximately 10⁷ erg/cm³.

Additionally, MRAM of spin injection magnetization reversal type is expected to be a future high-density memory, on which studies a perpendicular magnetization film exhibiting a large Kᵤ value of approximately 10⁷ erg/cm³ is also used to increase the capacity.

Various studies have been made for such a perpendicular magnetization film demonstrating a Kᵤ value suitably used in magnetic recording media and memories. For example, the following techniques are disclosed.

Non-Patent Literature 1 discloses fabrication of L1₁ type Co—Pt ordered alloy films formed by sputtering deposition. Moreover, Non-Patent Literatures 2 and 3 disclose L1₀ type Fe—Pt ordered alloy films. Further, Patent Literatures 4 to 9 disclose L1₀ type ordered alloys such as a Fe—Pt ordered alloy, a Fe—Pd ordered alloy, and a Co—Pt ordered alloy as well as magnetic recording media using such an L1₀ type ordered alloy for a magnetic layer. Note that the L1₁ type Co—Pt ordered alloy film disclosed in Non-Patent Literature 1 is capable of achieving a much higher order degree than conventional alloy films, and thus is expected to exhibit a particularly large Kᵤ value.

A magnetic thin film is not only one that determines the device performance through the improvement of its properties. Suitable example is an IrMn layer containing no ferromagnetic element of an exchange coupled element described in Patent Literature 2, because the order degree of the IrMn layer is considered important to improve the performance.

Further, to increase the recording density and enhance the performance in MRAM, the performance must be enhanced by increasing the magnetic resistance of the tunnel magneto-resistance element, in addition to Kᵤ. Non-Patent Literature 3 theoretically reaches a conclusion that the magnetic resistance of TMR is related to the spin polarization of a current flowing into the element; the higher the polarization, the higher the magnetic resistance. In order to increase the spin polarization of electrons, actively studied are a full-Heusler alloy which is known to have an ability to filter orientations of spins of electrons, and a magneto-resistance element using a full-Heusler alloy for an electrode. Generally, a full-Heusler alloy has an ordered phase of an L2₁ structure. The spin-filter effect of a full-Heusler alloy is a mechanism which works only when the alloy is in an ordered phase. Hence, the formation of an ordered phase is a key for the performance improvement.

### CITATION LIST

### Patent Literature

Patent Literature 1: Japanese Patent Laid-Open No. 2006-85825
Patent Literature 2: Japanese Patent Laid-Open No. 2005-333106
Patent Literature 3: Japanese Patent Laid-Open No. 2004-311925
Patent Literature 4: Japanese Patent Laid-Open No. 2002-208129
Patent Literature 5: Japanese Patent Laid-Open No. 2003-173511
Patent Literature 6: Japanese Patent Laid-Open No. 2002-216330
Patent Literature 7: Japanese Patent Laid-Open No. 2004-311607
Patent Literature 8: Japanese Patent Laid-Open No. 2001-101645
Patent Literature 9: International Patent Application Publication No. WO2004/034385
Patent Literature 10: Japanese Patent Laid-Open No. H05-266457 (1993)

### Non Patent Literature

Non-Patent Literature 1: H. Sato, at al., “Fabrication of L1₁ type Co—Pt ordered alloy films by sputter deposition,” J. Appl. Phys., 103, 07E114 (2008).
Non-Patent Literature 2: S. Okamoto, et al., “Chemical-order-dependent magnetic anisotropy and exchange stiffness constant of FePt (001) epitaxial films,” Phys. Rev. B, 66, 024413 (2002).
Non-Patent Literature 3: M. Julliere, “Tunneling between ferromagnetic films,” Phys., Lett., 54A, 225-226 (1975).

Now, problems in mass-producing various devices using an ordered alloy thin film and problems of conventional devices will be described.

Normally, high-temperature heating is required to obtain an ordered alloy having an ordered phase. For example, in order to orderly arrange a FePt alloy and a Co₂MnSi full-Heusler alloy, heating at approximately 700° C. is required. In this case, the softening temperature of the substrate used has to be sufficiently higher than the heating temperature. To fulfill this requirement, it is proposed that a single crystal having a high softening temperature be used as the substrate material to make the substrate endurable in the high-temperature heating. However, this substrate is not usable for mass production in terms of cost.

At present, in the mass production of magnetic recording media, an aluminium substrate greatly advantageous in cost is actually used. Generally, an aluminium substrate for magnetic recording medium is subjected to a surface smoothing treatment using a NiP plating. The NiP plating is amorphous immediately after the formation, but is crystallized by heating and increases its roughness. This brings about a problem of inhibiting stable flying of a head at a low height. Along with the increase in recording density of magnetic recording media in recent years, the flying height of heads for writing and reading a signal has been decreased to approximately several nm. In this situation, in order for the head to stably fly over the surface of a magnetic recording medium, the surface of the magnetic recording medium must be very smooth. By using the NiP plating normally crystallized at approximately 230° C. and having an increased roughness, it is difficult to meet the requirement that the head should stably fly at a low height.

Meanwhile, MRAM and MEMS devices require microfabrication employing electron beam lithography or the like after thin film formation. The increase in the surface roughness delimits the minimum size in the microfabrication, and may possibly increase the size variation of devices thus formed. Accordingly, the increase in the surface roughness should be avoided in any case.

Moreover, the electron beam lithography has a problem pointed out as follows. Specifically, electric charges are accumulated on the substrate. An electric field generated by the accumulated electric charges interacts with electron beams for lithography, and thereby deflects the electron beams. This problem can be solved by using a conductive material for a substrate. Accordingly, the use of aluminium for the substrate offers a great contribution in improving the quality stability of the microfabrication.

For the aforementioned reasons, an ordered alloy thin film using an aluminium substrate is yet to be suited to mass-production of perpendicular magnetic recording media. In addition, TMR, MRAM, and other devices are forced to use an expensive Si substrate because this substrate has a sufficient durability to the heating temperature.

### SUMMARY OF THE INVENTION

The present invention has been made in view of the above-described problems. An object of the present invention is to provide: a thin film structure including an ordered alloy in which atoms are orderly arranged using an inexpensive substrate; and a method for manufacturing the same. Another object of the present invention is to provide various devices using such a thin film structure, and methods for manufacturing the same.

One example for achieving the objects of the present invention is a thin film structure including a substrate, a plating layer formed on the substrate and made of one selected from the group consisting of NiPMo and NiPW, and an ordered alloy disposed on the plating layer. Here, the thin film structure preferably has a surface roughness (Ra) of 1.0 nm or less. The substrate preferably contains aluminium (Al). The substrate is preferably a nonmagnetic substrate. Moreover, it is preferable that a metal element forming the ordered alloy include at least one ferromagnetic element selected from the group consisting of iron (Fe), cobalt (Co), and nickel (Ni) and that the ordered alloy have magnetism.

Further, another example for achieving the objects of the present invention is a perpendicular magnetic recording medium, a tunnel magneto-resistance element, a magnetoresistive random access memory, or a micro-electromechanical system device, which include such a thin film structure.

Alternatively, still another example for achieving the objects of the present invention is a method for manufacturing a thin film structure, including the steps of: forming a plating layer on a substrate, the plating layer being made of one selected from the group consisting of NiPMo and NiPW; and forming an ordered alloy on the plating layer. A vacuum degree immediately before the ordered alloy is formed is 7.0×10⁻⁷ Pa or less, and in the step of forming the ordered alloy, a process gas has an impurity concentration of 5 ppb or lower. Here, in the step of forming the ordered alloy, the substrate preferably has a temperature of 300 to 325° C.

### BRIEF DESCRIPTION OF THE DRAWINGS

FIG. 1 is a schematic sectional view for illustrating an example of a perpendicular magnetic recording medium including a thin film structure of the present invention without a seed layer;

FIG. 2 is a schematic sectional view for illustrating a configuration example of the perpendicular magnetic recording medium including the thin film structure of the present invention with a seed layer;

FIG. 3 is a conceptual drawing for illustrating a configuration example of a tunnel magneto-resistance element including the thin film structure of the present invention;

FIG. 4 is a conceptual drawing for illustrating a configuration example of a magnetoresistive random access memory formed using the tunnel magneto-resistance element in FIG. 3;

FIG. 5 shows an example of the result of a read/write signal outputted from a magnetic recording medium prepared at a substrate temperature of 320° C. in Experimental Example 1;

FIG. 6 shows an example of the result of a read/write signal outputted from a magnetic recording medium prepared at a substrate temperature of 320° C. in Comparative Example 1;

FIG. 7 shows the XRD results of magnetic recording media prepared at a substrate temperature of 320° C. in Experimental Examples 1 to 3;

FIG. 8 shows the XRD results of magnetic recording media prepared at a substrate temperature of 240° C. in Experimental Examples 1 to 3;

FIG. 9 shows a magnetization curve of the magnetic recording medium prepared at a substrate temperature of 320° C. in Experimental Example 1;

FIG. 10 shows a magnetization curve of the magnetic recording medium prepared at a substrate temperature of 240° C. in Experimental Example 1;

FIG. 11 shows a magnetization curve of the magnetic recording medium prepared at a substrate temperature of 320° C. in Experimental Example 3; and

FIG. 12 shows a magnetization curve of the magnetic recording medium prepared at a substrate temperature of 240° C. in Experimental Example 3.

### DESCRIPTION OF THE EMBODIMENTS

To begin with, description will be given of various application devices using the thin film structure described above, particularly application examples of a magnetic thin film structure. It should be noted that examples described below are merely exemplary of the present invention, and can be modified in design within the scope of the present invention as appropriate by those skilled in the art.

### (Magnetic Recording Medium)

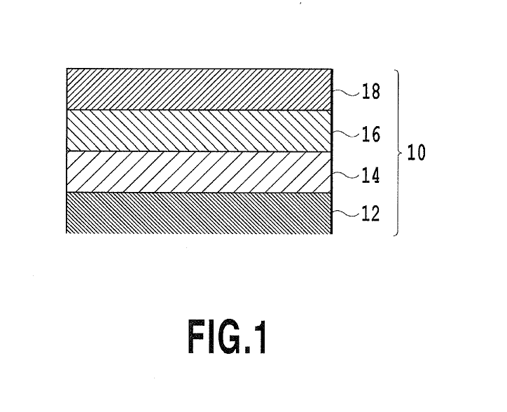

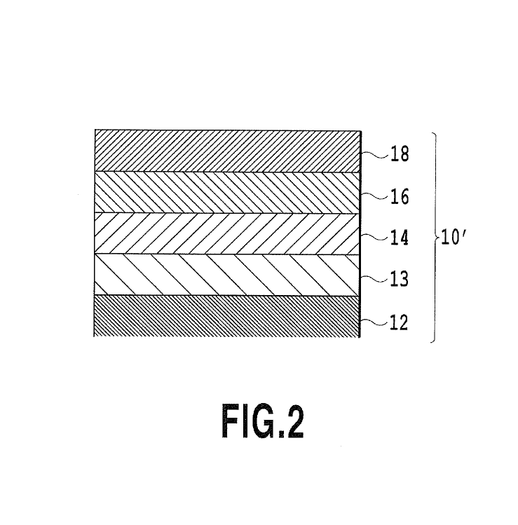

FIGS. 1, 2 are sectional views for illustrating examples of a perpendicular magnetic recording medium formed using a thin film structure of the present invention. FIG. 1 shows a perpendicular magnetic recording medium including an underlayer, a magnetic layer as an ordered alloy, and a protective layer sequentially formed on a substrate. FIG. 2 shows the perpendicular magnetic recording medium in the example illustrated in FIG. 1, further including a seed layer formed between the substrate and the underlayer. The seed layer is provided in order to suitably control an excellent crystal orientation and/or an excellent crystal grain diameter of the underlayer.

In FIGS. 1, 2, a substrate 12 is a constituent placed at the lowest portion of a perpendicular magnetic recording medium 10 or 10′ and configured to support the other constituents of the medium. The other constituents are sequentially formed on the substrate 12 and will be described later. As the substrate 12, it is preferable to use a nonmagnetic substrate made of aluminium, an aluminium alloy, or the like.

In the present invention, an unillustrated plating layer is formed on the substrate 12. The plating layer is made of one selected from the group consisting of NiPMo and NiPW.

Amounts of P and Mo introduced into the NiPMo plating layer are desirably determined in accordance with a required thermal durability of the substrate. In consideration of polishability, control easiness of a plating bath, and so forth, it is more desirable that Ni be 85.2 to 89.1% by weight, P be 10.7 to 13.0% by weight, and Mo be 0.2 to 1.8% by weight. In this case, the Mo content below 0.2% by weight reduces the nonmagnetic properties. Meanwhile, the Mo content exceeding 1.8% by weight decreases the phosphorus content, reducing the nonmagnetic properties in this case as well. Moreover, the P content below 10.7% by weight also reduces the nonmagnetic properties. The P content exceeding 13.0% deteriorates the appearance of the plating layer, and deteriorates the surface roughness.

Amounts of P and W introduced into the NiPW plating layer are also desirably determined in accordance with a required thermal durability of the substrate. In consideration of polishability, control easiness of a plating bath, and so forth, it is more desirable that Ni be 78.0 to 92.5% by weight, P be 7.0 to 15.0% by weight, and W be 0.5 to 7.0% by weight. In this case, the W content below 0.5% by weight brings about a problem of reducing the nonmagnetic properties. Meanwhile, the W content exceeding 7.0% by weight decreases the phosphorus content, reducing the nonmagnetic properties in this case as well. Moreover, the P content below 7.0% by weight also reduces the nonmagnetic properties. The P content exceeds 15.0% deteriorates the appearance of the plating layer, and deteriorates the surface roughness.

As the method for forming the plating layer, an electroless plating method using an electroless NiPMo or NiPW plating bath is preferably adopted. In this case, the plating bath used contains an aqueous nickel salt, an aqueous molybdic acid salt or an aqueous tungstic acid salt, hypophosphorous acid or a salt thereof, and a complexing agent. The plating bath may have any composition, as long as the plating layer having the above-described composition is obtained.

Note that, to the electroless plating bath, components including a pH adjuster and a stabilizer such as a lead salt may be added. The pH of the electroless plating bath is preferably acidic, particularly preferably in the range of 4 to 5.

When the plating layer is formed on the substrate using the plating bath, the substrate may be pretreated according to an ordinary method, and then immersed in the plating bath. The plating is performed normally at a temperature of 70 to 95° C. In addition, when the plating is performed, the plating bath is preferably stirred as appropriate by a process such as stirring with a stirrer, stirring with a pump, or shaking the plated object. Such stirring reliably enables the preparation of the nonmagnetic plating layer having a good thermal durability. Note that, in the present invention, the plating layer preferably has a thickness of 1 to 30 μm, particularly preferably 5 to 15 μm.

An underlayer 14 is a constituent placed and configured to improve the orientation of a magnetic layer 16 made of an ordered alloy to be described later, control the grain diameter of the magnetic layer 16, and restrict generation of an initial growth layer at the time of forming the magnetic layer 16. In order for the underlayer 14 to demonstrate such functions sufficiently, the structure needs to be considered while taking into account appropriate control of the crystal structure and the crystal orientation plane of the magnetic layer 16 growing on the underlayer 14. For example, when an L1₀-FePt ordered alloy is used for the perpendicular magnetic recording medium 10 or 10′, the FePt (002) plane has to be arranged parallel to a film surface. Accordingly, the material of the underlayer 14 preferably has the same crystal structure as that of the alloy and has a (002) plane arranged parallel to the film surface.

The magnetic layer 16 is a constituent placed and configured to record information, and is formed as the ordered alloy. The magnetic layer 16 is a single layer or has a laminated structure of two or more layers. In the case of the laminated structure, at least one layer thereof may be the ordered alloy. The configuration and the manufacturing method will be described later in Experimental Examples and so forth.

A protective layer 18 is a constituent placed and configured to protect the magnetic layer 16 and the layers located below shown in the cross-sectional views of the perpendicular magnetic recording media 10, 10′ in FIGS. 1, 2, and particularly when the magnetic layer 16 is a granular film, prevent elution of a ferromagnetic element of the magnetic layer 16. For the protective layer 18, it is possible to use materials normally used in a perpendicular magnetic recording medium. Examples of the materials include various thin layer materials known to be used for a protective layer made mainly of carbon such as diamond-like carbon (DLC) or amorphous carbon (preferably, diamond-like carbon (DLC)), or for a protective layer of a magnetic recording medium. The thickness of the protective layer 18 may be equal to a thickness of a constituent normally adopted in a perpendicular magnetic recording medium.

In the perpendicular magnetic recording medium 10′ of FIG. 2, a seed layer 13 is further formed between the substrate 12 and the underlayer 14. The seed layer 13 is a constituent placed and configured to suitably control the orientation of the underlayer 14 formed as an upper layer of the seed layer 13, thereby achieving a good perpendicular orientation of the magnetic layer 16.

Further, the perpendicular magnetic recording media 10, 10 shown in FIGS. 1, 2 may include layers other than the layers disclosed in these drawings.

For example, a soft magnetic backing layer unillustrated may be formed on the substrate 12. The soft magnetic backing layer is a constituent configured to sufficiently secure a magnetic field in a perpendicular direction so as to prevent spread of a magnetic flux generated from a head at the time of recording information. As the material for the soft magnetic backing layer, a Ni alloy, a Fe alloy, or a Co alloy may be used. Particularly, the use of amorphous Co—Zr—Nb, Co—Ta—Zr, Co—Ta—Zr—Nb, Co—Fe—Nb, Co—Fe—Zr—Nb, Co—Ni—Fe—Zr—Nb, Co—Fe—Ta—Zr—Nb, and the like can produce good electromagnetic conversion characteristics.

The above-described layers such as the underlayer 14, the magnetic layer 16, the protective layer 18, the seed layer 13, the soft magnetic backing layer, and so forth may be formed by adopting any condition and method which are known in the art, for example, sputtering (including DC magnetron sputtering, RF magnetron sputtering, and the like), vacuum deposition, or the like.

Additionally, a lubricant layer unillustrated may be formed on the protective layer 18. Although an optional constituent, the lubricant layer is a liquid constituent placed and configured to reduce a friction force generated between the protective layer and a head unillustrated in FIGS. 1, 2 so as to obtain excellent durability and reliability of the perpendicular magnetic recording medium. As the material for lubricant layer, it is possible to use materials normally used in a perpendicular magnetic recording medium. Examples of the materials include perfluoropolyether lubricants and the like. The thickness of the lubricant layer may be equal to a thickness of a constituent normally adopted in a perpendicular magnetic recording medium. The lubricant layer can be formed by using any coating method known in the art such as a dip coating method and a spin coating method.

### (Tunnel Magneto-Resistance Element (TMR) and Magnetoresistive Random Access Memory (MRAM))

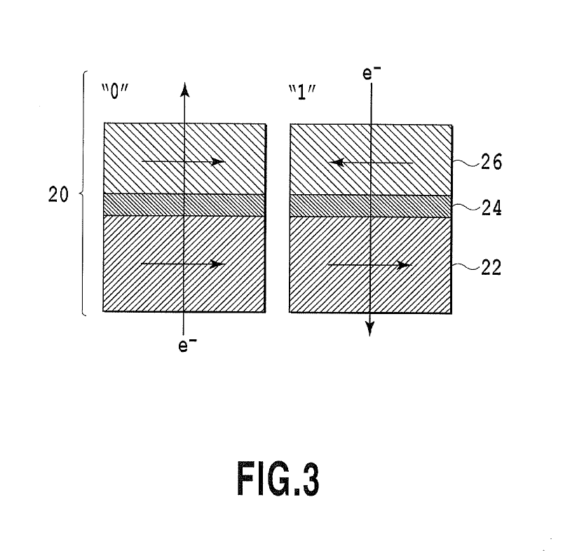

FIG. 3 is a conceptual drawing for illustrating a configuration example of a tunnel magneto-resistance element formed using the thin film structure of the present invention.

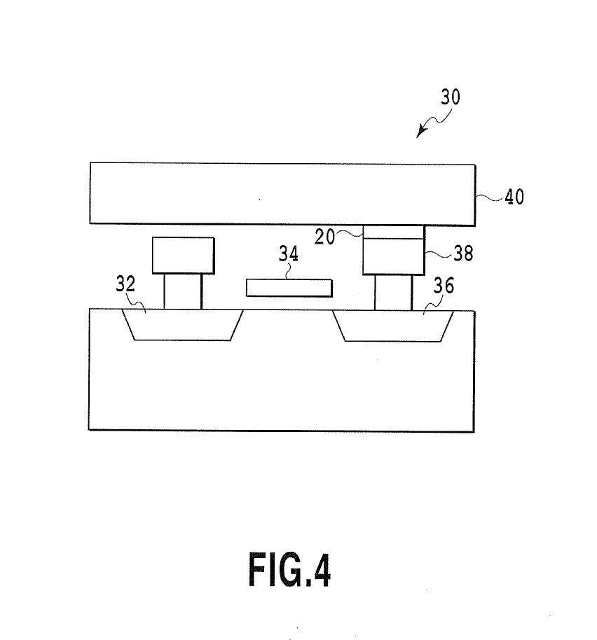

FIG. 4 is a conceptual drawing for illustrating a configuration example of a magnetoresistive random access memory formed using the tunnel magneto-resistance element in FIG. 3.

As shown in FIG. 3, a tunnel magneto-resistance element 20 is a laminate in which a fixed magnetic layer 22, a barrier layer 24, and a free magnetic layer 26 are sequentially formed.

The free magnetic layer 26 is a magnetic layer capable of changing an orientation of magnetization with a current flowing into the tunnel magneto-resistance element 20 or a magnetic field applied from the outside.

The barrier layer 24 is a constituent placed as a barrier configured to flow a tunnel current between the free magnetic layer 26 and the fixed magnetic layer 22 described in detail below. The barrier layer 24 may be formed using an oxide thin film such as magnesium oxide (MgO) or aluminium oxide (Al₂O₃). The barrier layer 24 may be formed by adopting any condition and method which are known in the art, for example, sputtering (including DC magnetron sputtering, RF magnetron sputtering, and the like), vacuum deposition, or the like.

The fixed magnetic layer 22 is a constituent placed as a magnetic layer having an orientation of magnetization unchanged even when a current or an external magnetic field is applied to the tunnel magneto-resistance element 20. The difference in orientation of magnetization between the fixed magnetic layer 22 and the free magnetic layer 26 can change the magnitude of a tunnel current flowing in the barrier layer 24.

The thin film structure (particularly, the magnetic thin film structure) of the present invention can be used as at least one of the free magnetic layer 26 and the fixed magnetic layer 22. The configuration and the manufacturing method of the thin film structure have been described in detail in the previous section, and are accordingly omitted here.

The tunnel magneto-resistance element 20 having such a configuration is operated by changing the orientation of magnetization of the free magnetic layer 26 with a current or an external magnetic field supplied to the element. Specifically, as shown in FIG. 3, the tunnel magneto-resistance element 20 is operated by reversibly changing a state in which the orientations of magnetization of the fixed magnetic layer 22 and the free magnetic layer 26 are parallel to each other (left side in the drawing) to a state in which the orientations of magnetization of these layers are anti-parallel to each other (right side in the drawing).

The orientations of magnetization of the free magnetic layer 26 and the fixed magnetic layer 22 may be in a state in which the orientations of magnetization of the two layers are parallel or anti-parallel to each other in in-plane directions of the free magnetic layer 26 and the fixed magnetic layer 22 as shown in FIG. 3. Alternatively, the orientations of magnetization of the free magnetic layer 26 and the fixed magnetic layer 22 may be in a state in which the orientation of magnetization of each of the layers is in a direction perpendicular to the two layers while the orientations of magnetization of the two layers are parallel or anti-parallel to each other. Note that “0” and “1” shown in the drawing mean signals of 0 and 1, respectively, when the tunnel magneto-resistance element is used as a memory. Further, the arrow lines in a horizontal direction represent examples of the orientations of magnetization, and the arrow lines denoted by “e⁻” represent examples of directions in which electrons flow.

Next, the tunnel magneto-resistance element 20 may be used while incorporated in a magnetoresistive random access memory 30 as shown in FIG. 4. As shown in the drawing, the magnetoresistive random access memory 30 includes: a MOS-FET having a source 32, a drain 36, and a gate 34; the tunnel magneto-resistance element 20 connected to the MOS-FET through a contact 38; and a bit line 40 formed thereabove.

The magnetoresistive random access memory 30 shown in FIG. 4 can be formed using a known technique.

The magnetoresistive random access memory 30 having such a configuration is capable of functioning as a memory configured to store digital information by the function of the tunnel magneto-resistance element 20 on the basis of the configuration shown in FIG. 4.

### (Other Device)

Although unillustrated, another application device using the magnetic thin film structure of the present invention can be a micro-electromechanical system (MEMS) device. The micro-electromechanical system device can be formed using a known technique by incorporating the magnetic thin film structure into a given member.

### EXAMPLES

Next, description will be given of experiments conducted to reveal the effects of the present invention. In the experiments, multiple ordered alloys were used for magnetic layers particularly important in the device application. Meanwhile, ordered alloys normally have crystal phases of a stable phase and a metastable phase. For example, an CoPt alloy is well-known to have an L1₀ phase as a stable phase and an L1₁ phase and m-D0₁₉ phase as metastable phases. This time, in order to check the effects of both the stable phase and the metastable phase, the experiments were conducted using a FePt alloy for the L1₀ phase and a CoPt alloy for the L1₁ phase and m-D0₁₉ phase. The experiments were carried out under conditions of Experimental Examples and Comparative Example in Table 1 shown below.

TABLE 1
Conditions of Experimental Examples and Comparative Example

| | | | Vacuum degree | | |
|---|---|---|---|---|---|
| | Magnetic | Plated | before film | | |
| | layer | species | formation | Gas purity | |
| Experimental | L1₀-FePt | NiPMo | 7.0 × 10⁻⁷ Pa | 2 to 3 | ppb |
| Example 1 | | | | | |
| Experimental | L1₀-FePt | NiPW | 7.0 × 10⁻⁷ Pa | 2 to 3 | ppb |
| Example 2 | | | | | |
| Experimental | Ll₁-CoPt | NiPMo | 7.0 × 10⁻⁷ Pa | 2 to 3 | ppb |
| Example 3 | | | | | |
| Experimental | m-D0₁₉-CoPt | NiPMo | 7.0 × 10⁻⁷ Pa | 2 to 3 | ppb |
| Example 4 | | | | | |
| Experimental | L1₀-FePt | NiPMo | 5.0 × 10⁻⁴ Pa | 2 to 3 | ppb |
| Example 5 | | | | | |
| Experimental | L1₀-FePt | NiPMo | 7.0 × 10⁻⁷ Pa | 5 | ppm |
| Example 6 | | | | | |
| Comparative | L1₀-FePt | NiP | 7.0 × 10⁻⁷ Pa | 2 to 3 | ppb |
| Example 1 | | | | | |

### Experimental Example 1

A NiPMo plating layer was formed on an aluminium substrate. The NiPMo plating layer had a composition of Ni₈₇P₁₂Mo₁ (meaning 87% by weight of Ni, 12% by weight of P, and 1% by weight of Mo. The same applies hereinafter). The composition of a plating bath used in this experiment was as follows. It should be noted that the following composition is merely exemplary, and can be modified in design within the scope of the present invention as appropriate.

nickel nitrate: 6.00 g/l

sodium hypophosphite: 30 g/l

sodium molybdate: 0.25 g/l

malic acid: 18 g/l

succinic acid: 16 g/l

stabilizer: a little

pH: 4.5

An electroless plating bath having the composition stated above was prepared. An aluminium substrate was subjected to a zinc immersion process as a plated sample, and plated at 90° C. for 120 minutes on while stirred with a stirrer. Then, the substrate surface was polished to reduce the surface roughness and make the plating layer have a thickness of 10 micron. After the plating layer was formed, the plating layer was next heated using an electric oven at 150° C. for 1 hour, to release a strain of the plating layer.

On the aluminium substrate having the aforementioned NiPMo plating, a sample having an easy axis of magnetization oriented in a perpendicular direction was formed using an UHV DC/RF magnetron sputtering system (ANELVA, E8001) as follows. The ultimate vacuum degree before the start of the film formation was 7.0×10⁻⁷ Pa or less. An ultra-high purity Ar gas having an impurity concentration of 2 to 3 ppb was used as the process gas.

First, in order to increase the adhesion strength to the substrate, Ta was deposited to 5 nm. MgO was deposited to 1 nm on Ta. Then, as the nonmagnetic seed layer, 20-nm Cr was deposited on MgO. Here, Cr was used merely as an example to orient the easy axis of magnetization of an L1₀-FePt ordered alloy, which will be described later, in the perpendicular direction, and does not particularly influence the effect of this Experimental Example. MgO was formed to 5 nm as the underlayer on Cr. Ar was used as the process gas for all the film formation from the Ta layer to the MgO layer. The gas pressure during the film formation was set at 0.3 Pa. For the formation of the MgO layer, materials containing Mg and O at 1:1 were used as a target, and a thin film was formed by RF sputtering. During the thin film formation, only Ar was used as the gas, and no oxygen was added. The XRD peak position of the thin film thus formed was obtained using an XRD (X-ray Diffraction) system. The XRD peak position agreed well with that of MgO. In addition, the composition analysis using EDX (Energy Dispersive X-ray Spectrometer) also confirmed that the thin film was made of the materials containing Mg and O at 1:1. Furthermore, by simultaneously sputtering Fe and Pt, a FePt alloy was formed to 10 nm as the magnetic layer. Incidentally, the composition of FePt can be adjusted by changing the power applied to the Fe and Pt target. EDX revealed that the composition of the FePt alloy thin film in this Experimental Example contained 55 at. % of Fe and 45 at. % of Pt. Note that this composition is merely an example, and Even if the composition itself is not obtained, the effects described later can be demonstrated presumably as long as an L1ₒ phase is formed in FePt. The substrate temperature during the formation of the magnetic layer was set from 240 to 360° C., and the Ar gas pressure during the film formation was set at 3.0 Pa.

Then, to protect the film surface, Ta (5 nm)/Pt (2 nm) were formed at an Ar gas pressure 0.3 Pa. Note that, in the description of the laminated film, the left side of “/” represents an upper layer, while the right side represents a lower layer. Furthermore, in order to evaluate the applicability as a perpendicular magnetic recording medium, a head flying test was conducted after a liquid lubricant layer was deposited to 1 nm. The order degree of the magnetic recording medium thus prepared was evaluated by the XRD measurement, and calculated using the integrated intensity of (001) and (002) peaks derived from the ordered alloy. For example, the order degree of Experimental Example 1-1 in Table 2, 0.77, was obtained by dividing the value of a ratio of the integrated intensity of the (002) peak to the integrated intensity of the (001) peak obtained in the experiment by a ratio of the integrated intensity of the (002) peak to the integrated intensity of the (001) peak theoretically calculated with the case of thoroughly ordered configuration. Moreover, the surface roughness (Ra) was calculated through the measurement in the region of 1×1 micrometer using AFM (Atomic Force Microscope) system (manufactured by Veeco Instruments Inc.) Note that the film formation conditions described here are merely examples, and do not particularly influence the effect of this Experimental Example.

### Experimental Example 2

A Ni₈₇P₉W₄ plating layer was formed in place of NiPMo by using the same process in Experimental Example 1. The composition of a plating bath used in this experiment was as follows. Nevertheless, the following composition is merely exemplary, and can be modified in design within the scope of the present invention as appropriate.

nickel sulfate: 3.00 g/l

sodium hypophosphite: 16 g/l

sodium tungstaLe: 0 to 22.2 g/l

sodium citrate: 30 g/l

sodium lactate: 45 g/l

sodium tetraborate: 7.00 g/l

stabilizer: a little

pH: 5.0 to 8.6

By the same method as in Experimental Example 1, formed was a perpendicular magnetic recording medium including an L1₀-FePt ordered alloy on the aluminium substrate having the aforementioned NiPW plating. In this Experimental Example, the substrate temperature during the formation of the magnetic layer was set at 240 to 360° C.

### Experimental Example 3

On the aluminium substrate having the NiPMo plating layer described in Experimental Example 1, a CoPt thin film having an L1₁ type ordered phase and having an easy axis of magnetization in the perpendicular direction was formed according to the conditions described in Non-Patent Literature 1.

For the formation of the following thin film sample, an UHV DC/RF magnetron sputtering system (ANELVA, E8001) was used. The ultimate vacuum degree before the start of the film formation was 7.0×10⁻⁷ Pa or less. An ultra-high purity Ar gas having an impurity concentration of 2 to 3 ppb was used as the process gas.

First, in order to increase the adhesion strength to the substrate, Ta was deposited to 5 nm. Pt was deposited to 10 nm on Ta. Here, Pt was used merely as an example to orient the easy axis of magnetization of the L1₁ type CoPt, which will be described later, in the perpendicular direction, and does not particularly influence the effect of this Experimental Example. Ar was used as the process gas for the film formation of the Ta and Pt layers. The gas pressure was set at 0.3 Pa. Furthermore, by simultaneously sputtering Co and Pt, a CoPt alloy was formed to 10 nm as the magnetic layer. The composition of CoPt can be adjusted by changing the power applied to the Co and Pt target. EDX revealed that the composition of the CoPt alloy thin film in this Experimental Example contained 50 at. % of Co and 50 at. % of Pt. Note that this composition was within a suitable composition range for obtaining an L1₁ ordered phase, but the composition is merely an example. Even if the composition itself is not obtained, the effects described later can be demonstrated presumably, as long as an L1₁ ordered phase is formed in CoPt. The substrate temperature during the formation of the magnetic layer was set from 240 to 360° C., and the Ar gas pressure during the film formation was set at 3.0 Pa. Then, to protect the film surface, Ta (5 nm)/Pt (2 nm) were formed at an Ar gas pressure of 0.3 Pa.

### Experimental Example 4

On the aluminium substrate having the NiPMo plating described in Experimental Example 1, a CoPt thin film having a m-D0₁₉ type ordered phase and having an easy axis of magnetization in the perpendicular direction was formed by the following method.

For the formation of a thin film sample, an UHV DC/RF magnetron sputtering system (ANELVA, E8001) was used. The ultimate vacuum degree before the start of the film formation was 7.0×10⁻⁷ or less. An ultra-high purity Ar gas having an impurity concentration of 2 to 3 ppb was used as the process gas. First, in order to increase the adhesion strength to the substrate, Ta was deposited to 5 nm. Pt was deposited to 10 nm on Ta. Here, Pt was used merely as an example to orient the easy axis of magnetization of the m-D0₁₉ type CoPt, which will be described later, in the perpendicular direction, and does not particularly influence the effect of this Experimental Example. Ar was used as the process gas for the film formation of the Ta and Pt layers. The gas pressure was set at 0.3 Pa. Furthermore, by simultaneously sputtering Co and Pt, a CoPt alloy was formed to 10 nm as the magnetic layer. The composition of CoPt can be adjusted by changing the power applied to the Co and Pt target. EDX revealed that the composition of the CoPt alloy thin film in this Experimental Example contained 80 at. % of Co and 20 at. % of Pt. Note that this composition was within a suitable composition range for obtaining a m-D0₁₉ ordered phase, but the composition is merely an example. Even if the composition itself is not obtained, the effects described later can be demonstrated presumably, as long as am-D0₁₉ ordered phase is formed in CoPt. The substrate temperature during the formation of the magnetic layer was set from 240 to 360° C., and the Ar gas pressure during the film formation was set at 0.3 Pa. Then, to protect the film surface, Ta (5 nm)/Pt (2 nm) were formed at an Ar gas pressure of 0.3 Pa.

### Comparative Example 1

A NiP plating layer was formed on a disk by employing the same method as in Experimental Example 1, except that the NiP plating layer was formed using a plating bath having the following composition. After the plating layer was formed, the plating layer was heated at 150° C. for 1 hour to release a strain of the plating layer. Then, an L1₀-FePt thin film was formed by the same method as in Experimental Example 1. The composition of the plating bath used in this experiment was as follows. Nevertheless, the following composition is merely exemplary, and can be modified in design within the scope of the present invention as appropriate.

nickel nitrate: 5.95 g/l

hypophosphorous acid: 34 g/l

phosphorous acid: 94.1 to 114.9 g/l

stabilizer: a little

pH: 4.65

### Experimental Example 5

The aluminium substrate having the NiPMo plating was prepared by using the same method as in Experimental Example 1, except that the ultimate vacuum degree before the film formation was 5.0×10⁻⁴ Pa. Thus, an L1₀-FePt thin film was formed. Note that the impurity concentration of the process gas used was 2 to 3 ppb as in Experimental Example 1.

### Experimental Example 6

The aluminium substrate having the NiPMo plating was prepared by using the same method as in Experimental Example 1, except that the impurity concentration of the process gas was increased to 5 ppm. Thus, an L1₀-FePt thin film was formed. Note that the ultimate vacuum degree before the film formation was 7.0×10⁻⁷ Pa as in Experimental Example 1.

Table 2 shows the order degree, surface roughness (Ra), and head flyability of the medium prepared at a substrate temperature of 320° C. in each of Experimental Examples and Comparative Example.

TABLE 2
Order degree, surface roughness, and head flyability
at a substrate temperature of 320° C. in
Experimental Examples and Comparative Example

| | Experi- | Experi- | Compar- | Experi- | Experi- |
|---|---|---|---|---|---|
| | mental | mental | ative | mental | mental |
| | Example | Example | Example | Example | Example |
| | 1-1 | 2-1 | 1-1 | 5-1 | 6-1 |
| Plated | NiPMo | NiPW | NiP | NiPMo | NiPMo |
| species | | | | | |
| Substrate | 320 | 320 | 320 | 320 | 320 |
| temperature | | | | | |
| during | | | | | |
| magnetic | | | | | |
| layer | | | | | |
| formation | | | | | |
| (° C.) | | | | | |
| Order degree | 0.77 | 0.80 | 0.77 | 0.34 | 0.12 |
| Surface | 0.563 | 0.548 | 4.690 | 0.558 | 0.564 |
| roughness | | | | | |
| (nm) | | | | | |
| Head | stable | stable | unstable | stable | stable |
| flyability | | | | | |

Regarding the order degree directly linked to an increase in Kᵤ of a magnetic recording medium, an increase in the order degree due to ordering was observed under the conditions where the impurity concentration of the process gas was 2 to 3 ppb and the substrate temperature was 320° C. (Experimental Examples 1-1, 2-1, 5-1 and Comparative Example 1-1). Particularly, in Experimental Examples 1-1, 2-1 and Comparative Example 1-1, the values were much larger than 0.5. Further, regarding the vacuum degree before the film formation, in Experimental Examples 1-1, 2-1 and Comparative Example 1-1 in which the vacuum degree before the film formation was 7.0×10⁻⁷ Pa, the order degree exceeding 0.5 was obtained at a substrate temperature of approximately 320° C. In contrast, in Experimental Example 5-1 in which the vacuum degree before the film formation was 5.0×10⁻⁴ Pa, the order degree was just as small as 0.34. Thus, it can be seen that in order to obtain a high order degree in the temperature zone of this study, that is, at low temperature, it is necessary that the impurity gas concentration during the formation of the magnetic layer be approximately 2 to 3 ppb, preferably 5 ppb or lower, and that the vacuum degree before the film formation be 7.0×10⁻⁷ Pa or less.

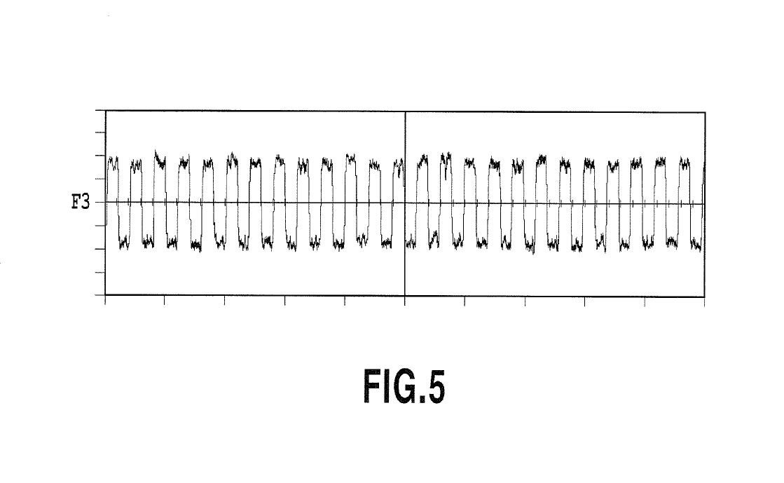

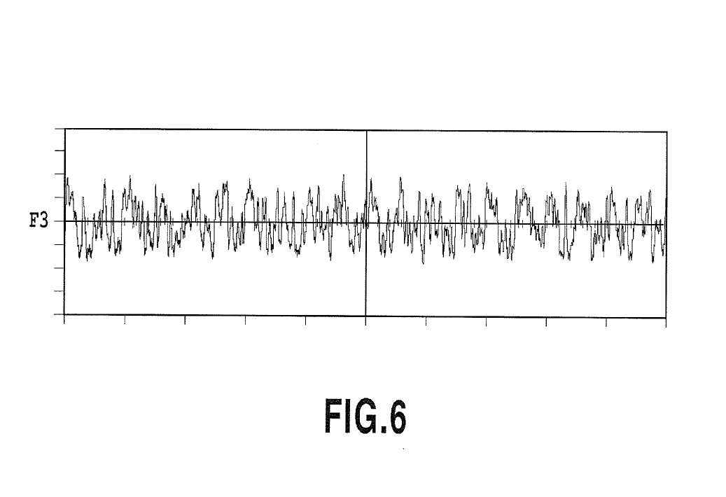

Next, regarding the surface roughness, it can be seen that all of the media obtained by using the NiPMo plating had a surface roughness of 1.0 nm or less. In contrast, in Comparative Example 1-1 in which the NIP plating was used, the surface roughness of the medium was significantly increased to 4.690 nm. FIGS. 5 and 6 show examples of the measurement result of read/write signals outputted from the media prepared at a substrate temperature of 320° C. in Experimental Example 1 and Comparative Example 1 (hereinafter, Experimental Example 1-1 and Comparative Example 1-1), respectively. In FIGS. 5, 6, the horizontal axis represents time, and the vertical axis represents a signal output. The track recording density in this case was 100 kFCI. In Experimental Example 1-1, the surface roughness was small. This indicates that a head can fly stably, and a square wave signal characteristic of a perpendicular magnetic recording medium is outputted. Meanwhile, in Comparative Example 1-1, the signal waveform was distorted. This suggests that the surface roughness was large and a head cannot fly stably.

To see the change due to the substrate temperature in detail, Tables 3 to 5 shows the order degree, surface roughness, and head flyability at various substrate temperatures in Experimental Example 1 (NiPMo plating), Experimental Example 2 (NiPW plating), and Comparative Example (NiP plating).

TABLE 3
Order degree, surface roughness, and head
flyability at various substrate temperatures in Experimental
Example 1

| | Substrate temperature during | | | | | | |
|---|---|---|---|---|---|---|---|
| | magnetic layer formation (° C.) | | | | | | |
| | 240 | 260 | 280 | 300 | 320 | 340 | 360 |
| Order | 0.48 | 0.61 | 0.66 | 0.75 | 0.77 | 0.80 | 0.86 |
| degree | | | | | | | |
| Surface | 0.512 | 0.513 | 0.524 | 0.540 | 0.663 | 0.883 | 1.373 |
| roughness | | | | | | | |
| (nm) | | | | | | | |
| Head flyability | stable | stable | stable | stable | stable | stable | unstable |

TABLE 4
Order degree, surface roughness, and
head flyability at various substrate temperatures in
Experimental Example 2

| | Substrate temperature during | | | | | | |
|---|---|---|---|---|---|---|---|
| | magnetic layer formation (° C.) | | | | | | |
| | 240 | 260 | 280 | 300 | 320 | 340 | 360 |
| Order | 0.50 | 0.62 | 0.68 | 0.74 | 0.80 | 0.82 | 0.85 |
| degree | | | | | | | |
| Surface | 0.487 | 0.499 | 0.511 | 0.525 | 0.648 | 0.869 | 1.377 |
| roughness | | | | | | | |
| (nm) | | | | | | | |
| Head | stable | stable | stable | stable | stable | stable | unstable |
| flyability | | | | | | | |

TABLE 5
Order degree, surface roughness, and
head flyability at various substrate temperatures in
Comparative Example 1

| | Substrate temperature during | | | | | | |
|---|---|---|---|---|---|---|---|
| | magnetic layer formation (° C.) | | | | | | |
| | 240 | 260 | 280 | 300 | 320 | 340 | 360 |
| Order | 0.45 | 0.58 | 0.65 | 0.73 | 0.77 | 0.80 | 0.82 |
| degree | | | | | | | |
| Surface | 0.521 | 1.081 | 2.810 | 4.080 | 4.690 | 5.231 | 5.542 |
| rough- | | | | | | | |
| ness | | | | | | | |
| (nm) | | | | | | | |
| Head | stable | unstable | unstable | unstable | unstable | unstable | unstable |
| fly- | | | | | | | |
| ability | | | | | | | |

First of all, regarding the surface roughness, when the substrates having the NiPMo or NiPW plating were used, the surface roughness was 1.0 nm or less in the substrate temperature zone of 340° C. or lower; it can be seen that a head can fly stably. In contrast, at 360° C., the roughness exceeded 1.0 nm; it can be seen that a head cannot fly stably. Meanwhile, when the NiP plating was used, the surface roughness was increased at around 260° C. or higher; it can be seen that the head flyability cannot be secured.

Next, regarding the order degree, it can be seen that any plated species had an order degree of approximately 0.5 in a low temperature zone from 240° C. This is because of the effect of low-temperature ordering by using a gas having a low gas impurity concentration as the process gas under a high vacuum degree condition.

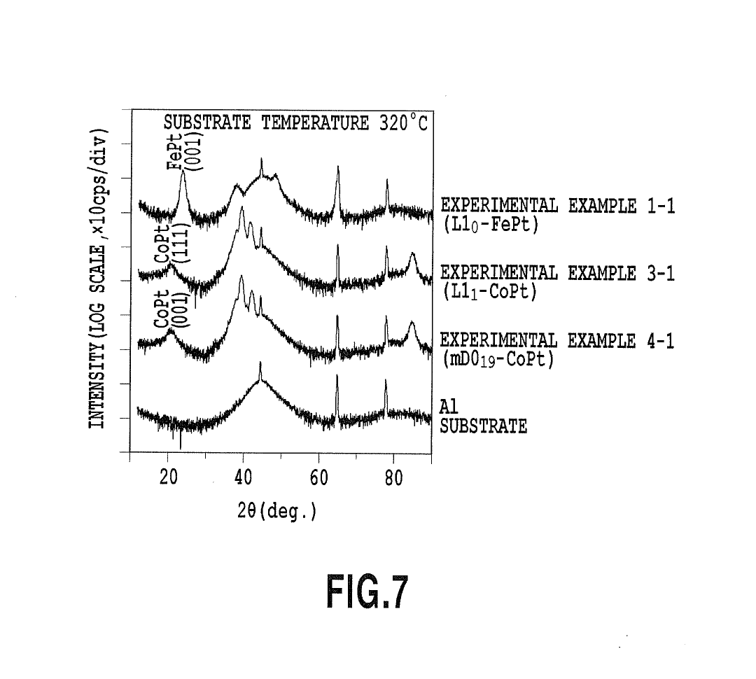

Next, ordered alloys other than L1₀-FePt were checked regarding whether or not the effects of the present invention were obtained. FIG. 7 shows the XRD results of samples of the thin film structures—prepared by setting the substrate temperature at 320° C., at which the head flyability can be secured, in Experimental Examples 1, 3, 4 (hereinafter, Experimental Examples 1-1, 3-1, 4-1). Diffraction lines observed at 20=around 24° were diffraction lines resulting from the orderly arrangement of atoms. Diffraction lines were observed from an L1₀-FePt (001) plane in Experimental Example 1-1, an L1₁-CoPt (111) plane in Experimental Example 3-1, and a m-D0₁₉-CoPt (001) plane in Experimental Example 4-1. It can be seen that ordered phases were formed in all the Examples.

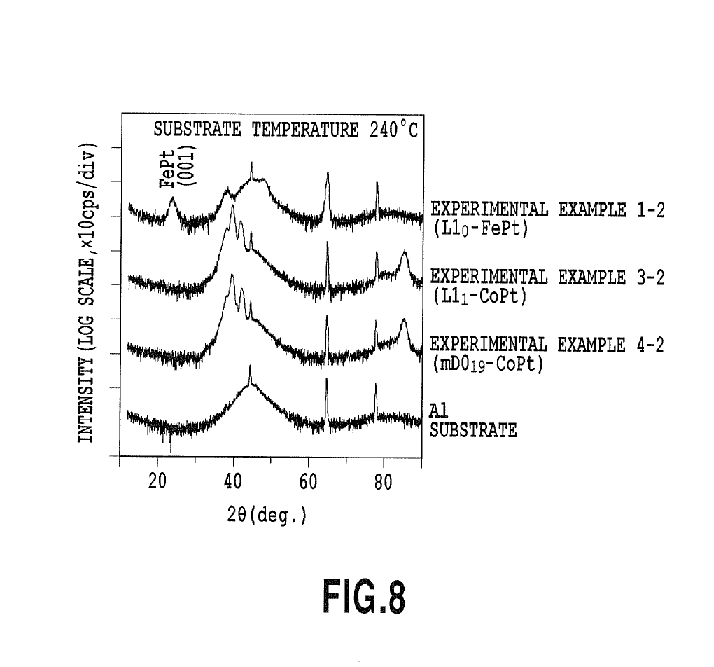

FIG. 8 shows the XRD results of samples prepared by lowering the substrate temperature to the temperature zone of 240° C., at which the NiP plating is usable, in Experimental Examples 1, 3, 4 (hereinafter Experimental Examples 1-2, 3-2, 4-2). A diffraction line resulting from the ordered phase was observed even at 240° C. from L1₀-FePt (Experimental Example 1-2) in which the ordered phase is a stable phase. However, no diffraction line resulting from the ordered phase was observed from L1₁-CoPt (Experimental Example 3-2) and m-D0₁₉-CoPt (Experimental Example 4-2) in which the ordered phase is a metastable phase.

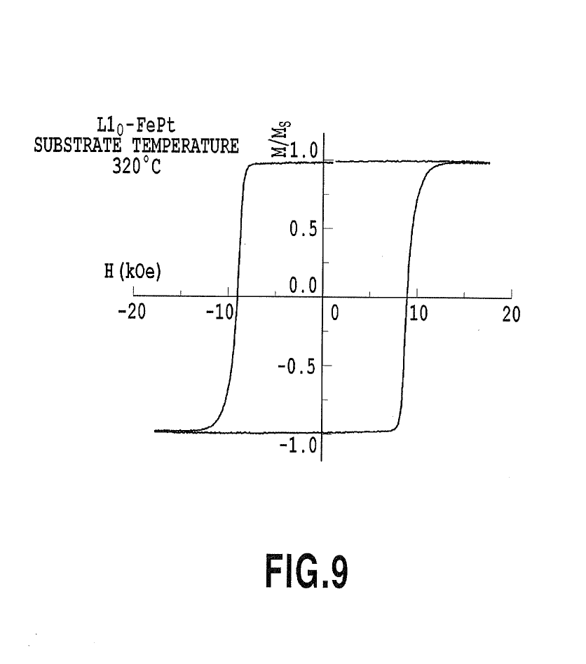

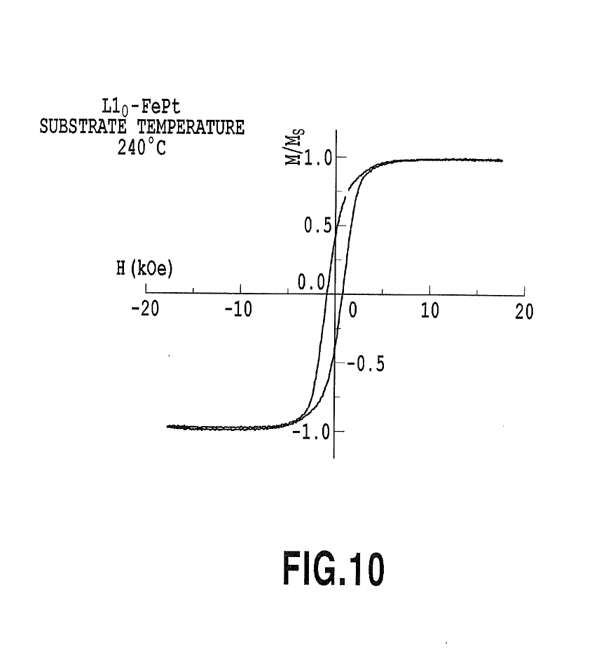

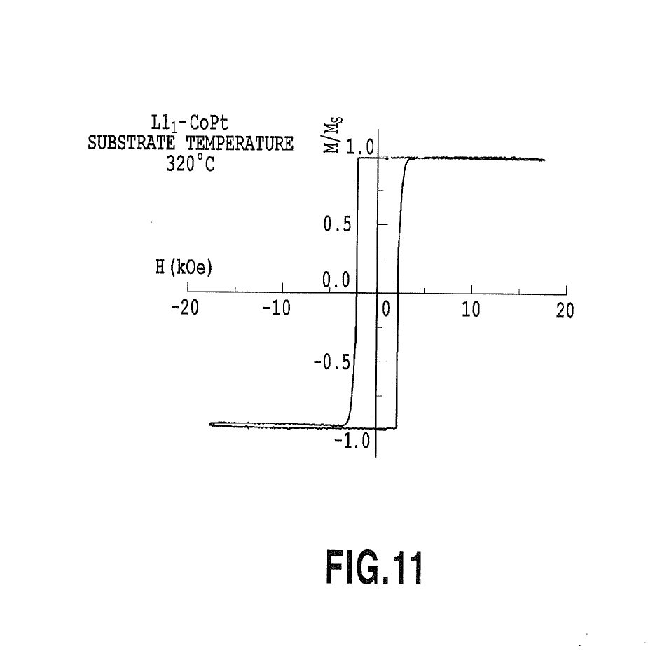

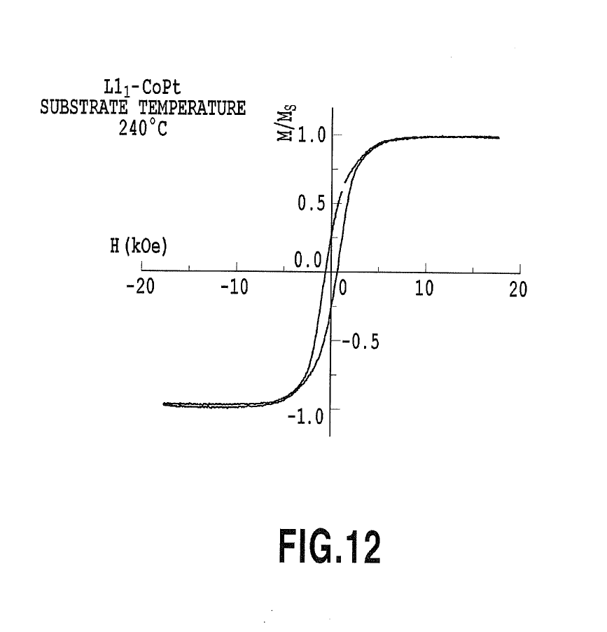

FIGS. 9, 10 show magnetization curves of the samples prepared at a substrate temperature of 320° C. and 240° C. in Experimental Example 1 (respectively, Experimental Examples 1-1 and 1-2). FIGS. 11, 12 show magnetization curves of the samples prepared at a substrate temperature of 320° C. and 240° C. in Experimental Example 2 (respectively, Experimental Examples 2-1 and 2-2). Here, the magnetization curves were obtained using magnetization curve measuring equipment utilizing the Kerr effect manufactured by NEOARK Corporation, and a direction in which a magnetic field was applied was the direction perpendicular to the film surface, that is, the direction of the easy axis of magnetization. The maximum magnetic field applied was set at 18 kOe, that is, at a magnetic field intensity at which the sample can be sufficiently saturated. At a substrate temperature of 320° C., a strong anisotropy resulting from the ordered phase was shown in the perpendicular direction in both Experimental Examples 1-1 and 2-1. However, it can be seen at a substrate temperature of 240° C. that no anisotropy was shown in both Experimental Examples 1-2 and 2-2. Although it can be seen from FIG. 8 that FePt was orderly arranged in Experimental Example 1-2, such a result was obtained presumably because the order degree and the anisotropic energy were small. Meanwhile, in Experimental Example 2-2, since no ordered phase existed at a substrate temperature of 240° C., a large anisotropy characteristic of an ordered phase was not shown. This would serve as a reason for explaining the shape of the magnetization curve.

The findings obtained from Experimental Examples have revealed that even for ordered alloys in a stable phase and a metastable phase represented by L1₀, L1₁, m-D0₁₉, and the like, the use of a high-purity sputtering gas successfully decreased the ordered-phase forming temperature to a temperature zone where an aluminium substrate plated with NiPMo or NiPW is usable. Note that even though such a high-purity sputtering gas was used, the ordered-phase forming temperature was not decreased to a temperature applicable to NiP. Nevertheless, it goes without saying that the results described herein are applied to ordered alloys in general.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

What is claimed is:

1. A thin film structure comprising:
a substrate;
a plating layer formed on the substrate and made of one selected from the group consisting of NiPMo and NiPW; and
an ordered alloy disposed on the plating layer.

2. The thin film structure according to claim 1, which has a surface roughness (Ra) of 1.0 nm or less.

3. The thin film structure according to claim 1, wherein the substrate contains aluminium (Al).

4. The thin film structure according to claim 1, wherein the substrate is a nonmagnetic substrate.

5. The thin film structure according to claim 1, wherein the ordered alloy includes at least one ferromagnetic element as a metal element selected from the group consisting of iron (Fe), cobalt (Co), and nickel (Ni).

6. A perpendicular magnetic recording medium comprising the thin film structure according to claim 5.

7. A tunnel magneto-resistance element comprising the thin film structure according to claim 5.

8. A magnetoresistive random access memory comprising the thin film structure according to claim 5.

9. A micro-electromechanical system device comprising the thin film structure according to claim 5.

10. A method for manufacturing a thin film substrate, comprising the steps of:
forming a plating layer on a substrate, the plating layer being made of one selected from the group consisting of NiPMo and NiPW; and
forming an ordered alloy on the plating layer, wherein
a vacuum degree immediately before the ordered alloy is formed is 7.0×10⁻⁷ Pa or less, and
in the step of forming the ordered alloy, a process gas has an impurity concentration of 5 ppb or lower.

11. The method for manufacturing a thin film structure according to claim 10, wherein, in the step of forming the ordered alloy, the substrate has a temperature of 300 to 325° C.
